(19) United States
(12) Patent Application Publication
(10) Pub. No.: US 2003/0186536 A1
(43) Pub. Date: Oct. 2, 2003

(54) Via formation in integrated circuits by use of sacrificial structures

(76) Inventor: Michael F. Brenner, Dallas, TX (US)

Correspondence Address: TEXAS INSTRUMENTS INCORPORATED, P O BOX 655474, M/S 3999, DALLAS, TX, 75265

(21) Appl. No.: 10/113,008

(22) Filed: Mar. 29, 2002

(51) Int. Cl. H01L 21/3205

(52) U.S. Cl. 438/637

(57) ABSTRACT

A method of forming vias for an integrated circuit. A sacrificial pillar-like structure is fabricated over a metal line, where the via is to be. This sacrificial structure is then encapsulated by an insulating layer. The insulating layer is etched back to expose the sacrificial structure, which may then be removed with a relatively gentle etch. Upon removal of sacrificial structure, the via is opened to the metal line.

### TECHNICAL FIELD OF THE INVENTION

This invention relates to fabrication of integrated circuits, and more particularly to a method for forming vias in such devices.

### BACKGROUND OF THE INVENTION

A typical digital integrated circuit comprises a number of transistors and other electrical elements. The functionality of the circuit depends on the interconnection of these elements. The interconnects consist of metal lines, also called leads. Leads on different layers are separated by interlayer dielectrics, which form insulating layers. These lateral leads are connected by forming vertical vias through the insulating layers and then filling the vias with metal. Modern integrated circuits can have as many as eight or more levels of metal interconnect, each separated by an insulating layer.

The process of forming an integrated circuit can be thought of as having two major parts: the formation of the transistors and the formation of the interconning metal leads and vias. To form the vias by conventional methods, a layer of insulation is applied over a metal interconnect layer, such as by chemical vapor deposition. A typical material for the insulating layer is silicon dioxide. A photoresist pattern is formed by applying a photo-imagable resin (photoresist) over the insulating layer and exposing the surface of that layer with the desired via pattern. The pattern defines “holes” from which the photoresist is removed to expose the insulating layer. By means of etching, the pattern is transferred to the insulating layer, thus forming the via. After the via pattern is transferred, the photoresist is removed.

A problem with the above-described via formation method is that the etching process, which is anistropic, toughens the patterning materials, making the patterning materials more difficult to remove. The etching also leaves tough residues on the via sidewalls. To remove these residues, several wet and dry cleanup steps must be performed before the device can be processed further.

### SUMMARY OF THE INVENTION

One aspect of the invention is a method of forming a via for an integrated circuit. A sacrificial pillar-like structure is fabricated over a metal line of the integrated circuit. This pillar-like structure may be made of photoresist, formed using conventional photolithography techniques. An insulating layer is applied, such that the insulating layer encapsulates the pillar-like structure. This layer may be applied as a liquid film, such as by means of extrusion coating, which eliminates the need for additional planarization steps. Next, a portion of the insulating layer is removed so as to expose at least the top surface of the pillar-like structure. Finally, an isotropic etch is performed to remove the pillar-like structure.

An advantage of the present invention is that vias may be formed without an aggressive etch step. The more gentle etching process of the invention eliminates the need for clean-up steps that are required with more aggressive etching. Processing is greatly simplified and defect density is reduced.

A further advantage of the invention is realized when the insulating layer is applied with extrusion coating. Because the extrusion coating is “self-planarizing”, no subsequent planarization steps are needed. As a result, clean-up steps are eliminated and defects are further reduced.

### BRIEF DESCRIPTION OF THE DRAWINGS

FIG. 1 illustrates the basic steps of a method of forming vias in accordance with the invention.

FIG. 2 illustrates the formation of pillar-like structures over a metal lead of an integrated circuit.

FIG. 3 illustrates the application of an insulating layer over the pillar-like structure.

FIG. 4 illustrates the removal of a portion of the insulating layer to expose the top of the pillar-like structure.

FIG. 5 illustrates removal of the pillar-like structure.

FIG. 6 illustrates use of the via to interconnect leads on different layers of the integrated circuit.

### DETAILED DESCRIPTION OF THE INVENTION

FIG. 1 illustrates the basic steps of a method of forming vias in accordance with the invention. The invention is useful during fabrication of integrated circuits, where, as explained in the Background, vias are used to connect metal lines of various layers of the integrated circuit.

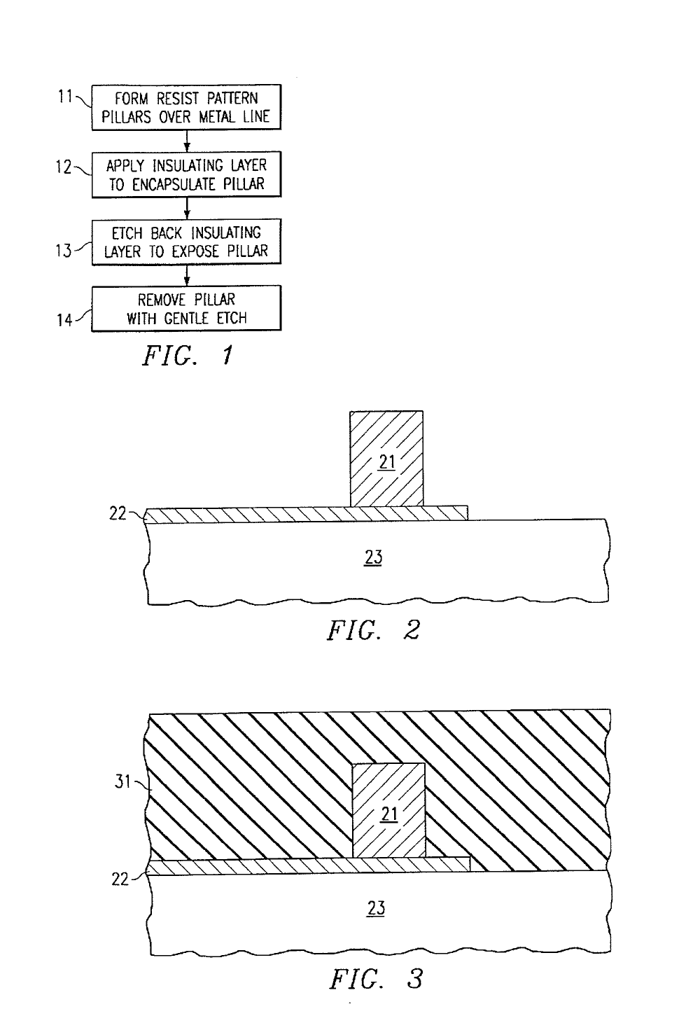

FIGS. 2-5 illustrate each of the steps of the method. The process for forming a single via in a semiconductor wafer are illustrated; a typical integrated circuit will have hundreds or thousands of such vias.

FIG. 2 illustrates Step 11, which is forming a pillar 21 over a metal line 22, which has already been patterned on a semiconductor substrate 23. Pillar 21 may be formed from photoresist, using conventional lithographic techniques, including patterning and etching. The material used to form pillar 21 is typically photoresist, but may be any “sacrificial” material, that may subsequently be removed as explained below. Pillar 21 need not be column-shaped, but rather may be any structure having a shape such that when sacrificially removed, will form a via.

FIG. 3 illustrates Step 12, which is applying an insulating layer 31. As illustrated, insulating layer 31 encapsulates pillar 21. Insulating layer 31 may be any material suitable for an interlevel dielectric layer of an integrated circuit. The deposition of layer 31 may be achieved by various means of deposition, such as by spin coating, extrusion coating, chemical vapor deposition, or aerosol or nebulized application.

Extrusion coating is especially desirable for applying layer 31 because of its ability to provide a planarized surface. In contrast, other deposition methods, such as chemical vapor deposition or spin coating, are conformal and require an etch bath or chemical mechanical planarization to achieve a desired planar surface.

For extrusion coating, the desired material may be applied in the form of a solution gel or liquid film. For liquid films, applied by extrusion coating, nebulization, or aerosol, application of the film may be followed by other processing, such as thermal or photochemical steps, in which the uniformity achieved through deposition is maintained. During these subsequent process steps, the chemical or physical structures of the film or underlying layers or interfaces may change, that is, these steps have a curing effect.

Experimental testing with extrusion coating has indicated that surface features may be coating and planarized to less than 250 angstroms. The same features covered by a spin coating were resulted in nonplanarities of approximately 1800 angstroms.

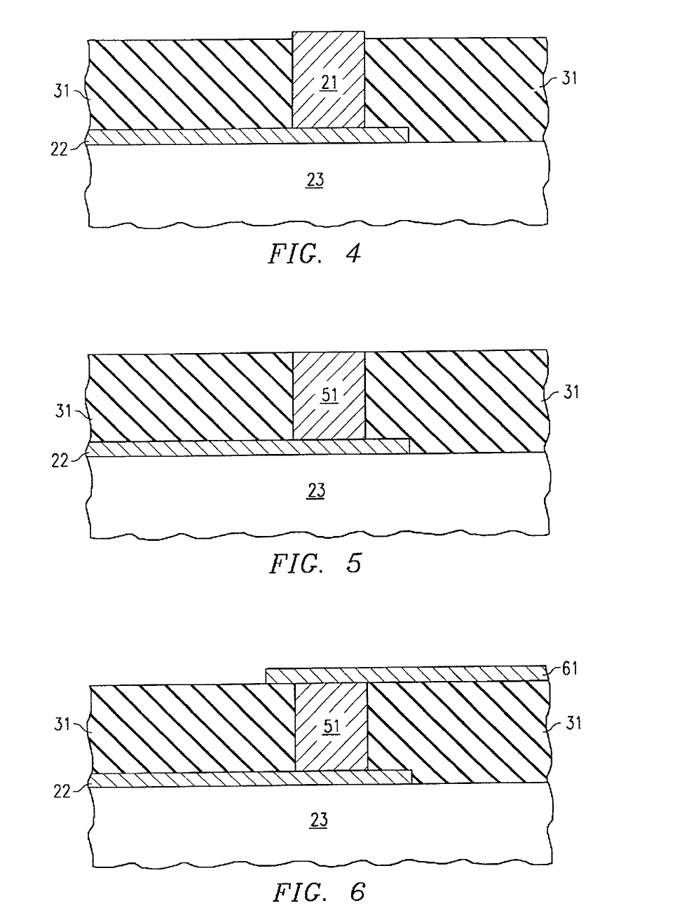

FIG. 4 illustrates Step 13, which is etching back insulating layer 31 to expose pillar 21. The etch may be either a wet or dry etch, such as a wet chemical or dry plasma etch. The etching is performed for a duration sufficient to expose at least the top surface of pillar 21.

FIG. 5 illustrates Step 14, which is removing pillar 21. This may be achieved with a relatively gentle etch, such as a gentle plasma etch. This type of plasma etch is commonly called an ash process, but other selective isotropic etches may be used, if suitable for removing the material from which pillar 21 is made may be used. The avoidance of anisotropic etching eliminates etch residue issues. After the sacrificial structure, that is, pillar 21, has been removed, a via 51 is formed in layer 31 and extends to metal line 22.

FIG. 6 illustrates how via 51 may be used to form a connection between two metal lines 22 and 62, separated by insulating layer 31. The via 51 contacts metal line 22 on one layer and metal line 62 on another layer.

### Other Embodiments

Although the present invention has been described in detail, it should be understood that various changes, substitutions, and alterations can be made hereto without departing from the spirit and scope of the invention as defined by the appended claims.

What is claimed is:

1. A method of forming a via for an integrated circuit having at least one metal layer with a metal connection line, comprising the steps of:
fabricating a sacrificial pillar-like structure on the metal line;
applying an insulating layer such that the insulating layer encapsulates the pillar-like structure;
removing a portion of the insulating layer to expose at least the top surface of the pillar-like structure; and
using an isotropic etch to remove the pillar-like structure.

2. The method of claim 1, wherein the insulating layer is applied as a liquid film.

3. The method of claim 2, wherein the liquid film is a solution gel.

4. The method of claim 2, wherein the insulating layer is applied as an extrusion coating.

5. The method of claim 2, wherein the insulating layer is applied by nebulization.

6. The method of claim 2, wherein the insulating layer is applied by aerosol deposition.

7. The method of claim 1, wherein the fabricating step is performed by photolithography.

8. The method of claim 1, wherein the pillar-like structure is made from photoresist.

9. The method of claim 1, wherein the insulating layer is made from silicon dioxide.

10. The method of claim 1, wherein the removing step is achieved with a wet chemical etch.

11. The method of claim 1, wherein the removing step is achieved with a dry plasma etch.

12. The method of claim 1, wherein the isotropic etch is a plasma etch.

13. The method of claim 1, wherein the isotropic etch is an ash etch.
